(19) United States
(12) Patent Application Publication
(10) Pub. No.: US 2026/0097675 A1
(43) Pub. Date: Apr. 9, 2026

(54) APPARATUS AND METHOD FOR CONTROLLING A VEHICLE

(71) Applicants: HYUNDAI MOTOR COMPANY, Seoul (KR); KIA CORPORATION, Seoul (KR); Auburn University, Auburn, AL (US)

(72) Inventors: Wooju Lee, Hwaseong-si (KR); Song-Yul Choe, Auburn, AL (US); Kyungjin Yu, Daegu (KR)

(73) Assignees: HYUNDAI MOTOR COMPANY, Seoul (KR); KIA CORPORATION, Seoul (KR); Auburn University, Auburn, AL (US)

(21) Appl. No.: 19/348,577

(22) Filed: Oct. 2, 2025

Related U.S. Application Data
(60) Provisional application No. 63/704,143, filed on Oct. 7, 2024.

(30) Foreign Application Priority Data
Aug. 20, 2025 (KR) 10-2025-0115737

(51) Int. Cl. B60L 53/62; G01R 31/367; G01R 31/382; G01R 31/396

(52) U.S. Cl. CPC B60L 53/62; G01R 31/367; G01R 31/382; G01R 31/396; B60L 2240/545

(57) ABSTRACT

A vehicle control apparatus predicts a state of a battery based on a battery model that reflects at least one of an electrical characteristic, a thermal characteristic, a degradation characteristic, or any combination thereof of the battery, determines a target charging current for shortening a charging time of the battery based on at least one of a negative pulse that induces stripping where metal plated from the battery is oxidized into metal ions, or the state of the battery, or any combination thereof, and charges the battery based on the target charging current.

### CROSS-REFERENCE TO RELATED APPLICATION

This application claims priority to and the benefit of U.S. Patent Application No. 63/704,143, filed on Oct. 7, 2024, and Korean Patent Application No. 10-2025-0115737, filed on Aug. 20, 2025, the entire contents of which are incorporated herein by reference.

### TECHNICAL FIELD

The present disclosure relates to a vehicle control apparatus and a method thereof, and more particularly, relates to a technology for charging a vehicle battery.

### BACKGROUND

Secondary batteries are utilized in a variety of applications due to their high energy density and excellent power output characteristics. In particular, with the spread of electrification technologies for vehicles, the demand for fast charging performance and long lifespan is increasing. Accordingly, various charging control methods are being researched to improve the charging efficiency of batteries and to simultaneously maintain safety and lifespan.

In the past, relatively simple charging protocols such as a constant current (CC) and a constant voltage (CV) methods are used, and are simple to implement. However, these protocols do not take into account the state or degraded state of the battery, which may lead to issues such as overcharging, lithium plating (Li-plating), and overheating. These issues may shorten the lifetime of the battery and, in severe cases, may affect safety.

Accordingly, advanced charge control technologies that precisely consider electrical, chemical, and thermal characteristics of a battery gain attention nowadays. For example, a method is proposed to measure or predict various variables such as temperature, voltage, resistance, and lifespan status of the battery and to adjust the charging current accordingly. In addition, a method (model-based control) of predicting the future state of the battery based on a battery model and controlling charging conditions based on the predicted result is also being actively researched.

In the meantime, because the performance of the model-based control is highly dependent on the accuracy of a prediction model, a state estimation technique (e.g., an algorithm such as the Kalman Filter) is also widely utilized to reduce the error between a measurement value of the actual battery and a model prediction value. Moreover, various control strategies for suppressing battery degradation phenomena such as Li-plating and heat generation that may occur during charging are being considered in parallel.

However, conventional technologies still include room for improvement in terms of real-time performance, accuracy, and coverage, and advanced charging control technologies that may flexibly respond to changes in battery status are required.

### SUMMARY

The present disclosure was made to solve the above-mentioned problems occurring in the prior art while advantages achieved by the prior art are maintained intact.

An aspect of the present disclosure provides a vehicle control apparatus and method capable of inducing lithium stripping by including a negative pulse in a current for charging a battery.

An aspect of the present disclosure provides a vehicle control apparatus and method capable of improving the lifespan and safety of the battery by removing lithium plated from a battery surface via lithium stripping.

An aspect of the present disclosure provides a vehicle control apparatus and method capable of determining whether to apply a negative pulse and determining an optimal charging current for a battery by reflecting the lithium stripping effect according thereto.

An aspect of the present disclosure provides a vehicle control apparatus and method capable of deriving the optimal charging current that satisfies both charging performance and safety by considering the metal stripping reaction induced by the negative pulse.

An aspect of the present disclosure provides a vehicle control apparatus and method capable of dynamically determining the optimal current for the battery, which is being charged, based on the battery's state data.

An aspect of the present disclosure provides a vehicle control apparatus and method capable of determining the amplitude of the negative pulse so as not to increase the overall charging time while minimizing the growth of lithium plated from the surface of the battery.

The technical problems to be solved by the present disclosure are not limited to the aforementioned problems, and any other technical problems not mentioned herein should be clearly understood from the following description by those having ordinary skill in the art to which the present disclosure pertains.

According to an aspect of the present disclosure, a vehicle control apparatus includes a memory that stores a program instruction and a processor that executes the program instruction. The processor predicts or determines a state of a battery based on a battery model that reflects or considers at least one of an electrical characteristic, a thermal characteristic, a degradation characteristic, or any combination thereof of the battery, determines a target charging current for shortening a charging time of the battery based on at least one of a negative pulse that induces stripping where metal plated from the battery is oxidized into metal ions, or the state of the battery, or any combination thereof, and charges the battery based on the target charging current.

In an embodiment, the processor may generate an algorithm for optimizing charging of the battery via the battery model, and may determine the target charging current by applying the algorithm to data associated with the state of the battery.

In an embodiment, the processor may determine the target charging current that minimizes or shortens the charging time of the battery while satisfying a charging condition for at least one of a heat generation rate of the battery, an extent to which plating of lithium (LiP) included in the metal is suppressed, an extent to which stripping of the lithium (LiS) is induced, or minimization of capacity degradation of the battery (or an extent to which capacity degradation of the battery is reduced), or any combination thereof.

In an embodiment, the processor may determine the target charging current including the negative pulse based on nonlinear model predictive control (NMPC).

In an embodiment, the processor may determine the target charging current including the negative pulse based on NMPC if a condition that the negative pulse is included in the target charging current is satisfied (or based on a condition that the negative pulse is included in the target charging current being satisfied). The condition that the negative pulse is included in the target charging current may include at least one of a condition that a charging time during which a constant current is applied exceeds a predetermined first reference time, or a condition that a charging time during which a current including the negative pulse is applied is less than or equal to a predetermined second reference time, or any combination thereof.

In an embodiment, the processor may determine amplitude of the negative pulse based on at least one of a first condition that a terminal voltage of the battery does not exceed (or is within) a range of a predetermined voltage, or a second condition that a difference between a metal ion concentration on a surface of the battery and an average metal ion concentration of the battery does not exceed (or is less than or equal to) a predetermined threshold value, or any combination thereof.

In an embodiment, the processor may determine amplitude of the negative pulse based on a third condition that current density at which the metal is plated from the battery does not exceed (or is less than or equal to) current density at which metal ions are stripped from the battery.

In an embodiment, the processor may determine the target charging current as a current for maintaining a predetermined voltage value based on a maximum or highest value of a terminal voltage of the battery exceeding the predetermined voltage value.

In an embodiment, the processor may identify data associated with the state of the battery by using one or more sensors installed in the battery. The data associated with the state of the battery may include at least one of State of Charge (SOC), State of Health (SOH), a terminal voltage of the battery, an overpotential at which the metal is plated from the battery, a metal ion concentration on a surface of the battery, an average metal ion concentration of the battery, current density at which the metal is plated from the battery, or current density at which metal ions are stripped from the battery, or any combination thereof.

In an embodiment, the processor may predict or determine the state of the battery based on a reduced-order physics-based model.

According to an aspect of the present disclosure, a vehicle control method includes predicting or determining, by a processor, a state of a battery based on a battery model that reflects or considers at least one of an electrical characteristic, a thermal characteristic, or a degradation characteristic, or any combination thereof of the battery, determining, by the processor, a target charging current for shortening a charging time of the battery based on at least one of a negative pulse that induces stripping where metal plated from the battery is oxidized into metal ions, or the state of the battery, or any combination thereof, and charging, by the processor, the battery based on the target charging current.

In the vehicle control method according to an embodiment, determining, by the processor, the target charging current for shortening the charging time of the battery may include generating, by the processor, an algorithm for optimizing charging of the battery via the battery model, and determining, by the processor, the target charging current by applying the algorithm to data associated with the state of the battery.

In the vehicle control method according to an embodiment, determining, by the processor, the target charging current for shortening the charging time of the battery may include determining, by the processor, the target charging current that minimizes or shortens the charging time of the battery while satisfying a charging condition for at least one of a heat generation rate of the battery, an extent to which plating of lithium (LiP) included in the metal is suppressed, an extent to which stripping of the lithium (LiS) is induced, or minimization of capacity degradation of the battery (or an extent to which capacity degradation of the battery is reduced), or any combination thereof.

In the vehicle control method according to an embodiment, determining, by the processor, the target charging current for shortening the charging time of the battery may include determining, by the processor, the target charging current including the negative pulse based on NMPC.

In the vehicle control method according to an embodiment, determining, by the processor, the target charging current for shortening the charging time of the battery may include determining, by the processor, the target charging current including the negative pulse based on NMPC if a condition that the negative pulse is included in the target charging current is satisfied (or based on a condition that the negative pulse is included in the target charging current being satisfied). The condition that the negative pulse is included in the target charging current may include at least one of a condition that a charging time during which a constant current is applied exceeds a predetermined first reference time, or a condition that a charging time during which a current including the negative pulse is applied is less than or equal to a predetermined second reference time, or any combination thereof.

In the vehicle control method according to an embodiment, determining, by the processor, the target charging current for shortening the charging time of the battery may include determining, by the processor, amplitude of the negative pulse based on at least one of a first condition that a terminal voltage of the battery does not exceed or is within a range of a predetermined voltage, or a second condition that a difference between a metal ion concentration on a surface of the battery and an average metal ion concentration of the battery does not exceed or is less than or equal to a predetermined threshold value, or any combination thereof.

In the vehicle control method according to an embodiment, determining, by the processor, the target charging current for shortening the charging time of the battery may include determining, by the processor, amplitude of the negative pulse based on a third condition that current density at which the metal is plated from the battery does not exceed or is less than or equal to current density at which metal ions are stripped from the battery.

In the vehicle control method according to an embodiment, determining, by the processor, the target charging current for shortening the charging time of the battery may include determining, by the processor, the target charging current as a current for maintaining a predetermined voltage value based on a maximum or highest value of a terminal voltage of the battery exceeding the predetermined voltage value.

The vehicle control method according to an embodiment may further include identifying or determining, by the processor, data associated with the state of the battery by using one or more sensors installed in the battery. The data associated with the state of the battery may include at least one of SOC, SOH, a terminal voltage of the battery, an overpotential at which the metal is plated from the battery, a metal ion concentration on a surface of the battery, an average metal ion concentration of the battery, current density at which the metal is plated from the battery, or current density at which metal ions are stripped from the battery, or any combination thereof.

In the vehicle control method according to an embodiment, predicting or determining, by the processor, the state of the battery may include predicting or determining, by the processor, the state of the battery based on a reduced-order physics-based model.

### BRIEF DESCRIPTION OF THE DRAWINGS

The above and other objects, features and advantages of the present disclosure should be more apparent from the following detailed description taken in conjunction with the accompanying drawings:

FIG. 1 is a block diagram illustrating a vehicle control apparatus, according to an embodiment of the present disclosure;

FIG. 2 is a block diagram illustrating a process in which a vehicle control apparatus according to an embodiment of the present disclosure applies a current determined based on a battery model and a charger algorithm to a battery;

FIG. 3A is a schematic diagram illustrating a microcell, according to an embodiment of the present disclosure;

FIG. 3B is a diagram illustrating a structure of an electrochemical-thermal-life model, according to an embodiment of the present disclosure;

FIG. 4 is a diagram showing an electrochemical mechanism, in which lithium ions are stripped by a vehicle control apparatus, according to an embodiment of the present disclosure;

FIG. 5A is a graph illustrating a simulation result showing that State of Health (SOH) of a battery is improved as a vehicle control apparatus according to an embodiment of the present disclosure includes a negative pulse in a target charging current;

FIG. 5B is a graph showing a simulation result showing that a charging time is shortened as a vehicle control apparatus according to an embodiment of the present disclosure includes a negative pulse in a target charging current;

FIG. 6A is a graph obtained by comparing trends of lithium concentration gradient changes in charging by a constant current and charging by a current including a negative pulse depending on Soc, according to an embodiment of the present disclosure;

FIG. 6B is a graph obtained by comparing changes in metal plating overpotential in charging by a constant current and charging by a current including a negative pulse depending on SOC, according to an embodiment of the present disclosure;

FIG. 7 is a diagram illustrating a process in which a vehicle control apparatus according to an embodiment of the present disclosure optimally determines a constant current magnitude and amplitude of a negative pulse using nonlinear model predictive control (NMPC);

FIG. 8 is a flowchart for describing a vehicle control apparatus or a vehicle control method, according to an embodiment of the present disclosure;

FIG. 9 is a flowchart illustrating a process for determining whether a vehicle control apparatus according to an embodiment of the present disclosure determines a target charging current including a negative pulse; and

FIG. 10 shows a diagram illustrating a computing system associated with a vehicle control apparatus or a vehicle control method, according to an embodiment of the present disclosure.

### DETAILED DESCRIPTION

Hereinafter, some embodiments of the present disclosure are described in detail with reference to the accompanying drawings. In adding reference numerals to components of each drawing, it should be noted that the same components include the same reference numerals, although they are indicated on another drawing. Furthermore, in describing embodiments of the present disclosure, detailed descriptions associated with well-known functions or configurations have been omitted if they may make subject matters of the present disclosure unnecessarily obscure.

In describing elements of an embodiment of the present disclosure, the terms first, second, A, B, (a), (b), and the like may be used herein. These terms are only used to distinguish one element from another element, but do not limit the corresponding elements irrespective of the nature, order, or priority of the corresponding elements. Moreover, the expression “at least one of A, B, or C or any combination thereof” may include “A, B, or C, or any combination thereof such as AB, BC, AC, or ABC”.

Furthermore, unless otherwise defined, all terms used herein, including technical or scientific terms, include the same meaning as commonly understood by one of ordinary skill in the technical field to which the present disclosure belongs. It should be understood that terms used herein should be interpreted as including a meaning that is consistent with their meaning in the context of the present disclosure and the relevant art and should not be interpreted in an idealized or overly formal sense unless expressly so defined herein. When a component, processor, controller, device, element, apparatus, or the like of the present disclosure is described as having a purpose or performing an operation, function, or the like, the component, processor, controller, device, element, apparatus, or the like should be considered herein as being “configured to” meet that purpose or to perform that operation or function. Each component, controller, device, element, apparatus, and the like may separately embody or be included with a processor and a memory, such as a non-transitory computer readable media, as part of the apparatus.

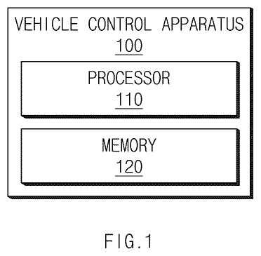

Hereinafter, embodiments of the present disclosure are described in detail with reference to FIGS. 1-10.

FIG. 1 is a block diagram illustrating a vehicle control apparatus, according to an embodiment of the present disclosure.

Referring to FIG. 1, a vehicle control apparatus 100 according to an embodiment of the present disclosure may be implemented inside a vehicle. The vehicle control apparatus 100 may be integrated with internal control units of a vehicle and may be implemented with a separate device so as to be coupled with control units of the vehicle via a separate connection device.

According to an embodiment, the vehicle control apparatus 100 may be implemented as part of a battery management system (BMS). The BMS is a system that monitors and manages the voltage, current, temperature, state of charge (SOC), or state of health (SOH) of a battery pack mounted in a vehicle, and includes hardware-based sensors and control circuits. The vehicle control apparatus 100 of the present disclosure may be implemented as a configuration including a memory and one or more processors running within the BMS, and may perform functions such as controlling charging current based on battery state information collected by the BMS, and determine an optimal charging profile. Accordingly, it is clear that the present disclosure is a concrete and technical way implemented via a physical system, not a mere mathematical algorithm or mental process.

According to an embodiment, the vehicle control apparatus 100 may include a processor 110 and a memory 120. The configuration of the vehicle control apparatus 100 shown in FIG. 1 is an example, and embodiments of the present disclosure are not limited thereto. For example, the vehicle control apparatus 100 may further include components not illustrated in FIG. 1.

According to an embodiment, the memory 120 may store instructions or data. For example, the memory 120 may store one instruction or two or more instructions that cause the vehicle control apparatus 100 to perform various operations if executed by the processor 110.

According to an embodiment, the memory 120 may be implemented as a single chipset with the processor 110 and may store various pieces of information associated with the vehicle control apparatus 100. For example, the memory 120 may store information about the operating history of the processor 110.

According to an embodiment, the memory 120 may include a non-volatile memory (a read only memory (ROM)) and a volatile memory (a random access memory (RAM)).

According to an embodiment, the processor 110 may predict the state of the battery based on a battery model that reflects at least one of electrical characteristics, thermal characteristics, or degradation characteristics, or any combination thereof of a battery.

According to an embodiment, the processor 110 may predict or determine the state of the battery based on information such as the state of charge (SOC), state of health (SOH), internal resistance, terminal voltage, current, and temperature of the battery.

According to an embodiment, the processor 110 may identify or determine data associated with the state of the battery by using sensors installed in the battery.

According to an embodiment, the data associated with the state of the battery may include at least one of SOC, SOH, a terminal voltage of the battery, an overpotential at which metal is plated from the battery, a metal ion concentration on the surface of the battery, an average metal ion concentration of the battery, current density at which metal is plated from the battery, or current density at which metal ions are stripped from the battery, or any combination thereof.

The SOC may be defined as a ratio (%) obtained by dividing a charge amount, which is stored in the battery, by a reference charge amount (a maximum charge storage amount or rated capacity). The SOC indicates how much the battery is currently charged, and thus it may be used as a key parameter in charging control.

The SOH may be an indicator of the battery's degradation state or overall performance level, and may be calculated by comprehensively reflecting the current battery's capacity, internal resistance, and output characteristics compared to an initial state (a new product). For example, if 90% of the initial capacity may be stored, the SOH is defined as 90%. The SOH may be used to predict the battery's lifespan and to determine charging conditions.

The terminal voltage of a battery may include the voltage measured via an external circuit between a cathode and an anode of the battery. The terminal voltage may indirectly reflect the battery's current charge state and internal electrochemical reaction.

The overpotential (plating overpotential) at which metal is plated in the battery may include a potential difference lower than a threshold potential required to initiate a plating reaction where metal ions react with electrons on the surface of the battery's anode and are reduced (plated) to solid metal. This represents the driving force of the plating reaction, and the plating may generally be induced if the overpotential is lower than 0 (if it is a negative value).

In detail, if a metal ion reaches the electrode surface, a certain electrochemical driving force is required for the corresponding ion to be reduced to a metal state via the electrochemical reaction, and the potential difference at this time may be understood as the overpotential at which the metal is plated.

If the overpotential becomes less than zero (i.e., if it is a negative value), this indicates that sufficient reduction force is provided to plate metal ions. Under the condition, a metal plating reaction may occur.

For example, in the case of a lithium-ion battery, if lithium ions move from the cathode to the anode via the electrolyte and are intercalated into the carbon-based anode, the charging rate is too fast, or the voltage conditions are excessive, the lithium ions may not be intercalated and may be plated in the form of metallic lithium on the surface of the anode. In this case, the metal plating overpotential may be used as an important reference variable to determine and control these plating conditions.

The metal ion concentration on the surface of the battery may include the concentration of metal ions present near the surface of the anode of the battery (near the solid-electrolyte interphase (SEI) layer). The concentration of metal ions on the surface of a battery may indicate the possibility that metal ions may reach and react with an electrode. For example, if the metal ion concentration is low, the concentration gradient may be intensified, thereby increasing the plating possibility of metals.

The average metal ion concentration of a battery may include the average concentration of metal ions distributed across the entire battery electrode (e.g., the anode) or an electrolyte region. The average metal ion concentration may be used to determine whether a concentration gradient between the electrode surface and the interior is formed. For example, if the difference from the surface concentration is great, the application of an excessive current may lead to the plating conditions.

The current density at which metal is plated in a battery may include the amount of current where metal ions are reduced to a metal form at the battery surface per unit area and an electrochemical reaction occurs. For example, if the current density at which metal is plated exceeds a threshold value, metal plating may accelerate, thereby leading to a reduced battery lifespan and safety issues.

The current density at which metal ions are stripped from the battery may include the current density of electrochemical reactions in which already plated metal is oxidized back to an ion form and diffuses into the electrolyte. For example, the processor 110 may induce a stripping current density via an appropriate negative pulse, thereby improving the safety and lifespan of the battery by removing pre-plated metal.

According to an embodiment, a battery model reflecting or considering at least one of electrical characteristics, thermal characteristics, or degradation characteristics, or any combination thereof of the battery may include at least one of an empirical model, an electric circuit model, a full-order physics-based model, or a reduced-order physics-based model, or any combination thereof.

According to an embodiment, the computational speed of the empirical model and the electric circuit model (ECM) is very fast in a method of approximating the operation of an actual battery by using simple mathematical equations or an R-C element-based circuit.

However, the empirical model and the electric circuit model fail to reflect and/or consider complex internal physical phenomena (e.g., lithium ion diffusion, changes in electrochemical reaction rates, degradation mechanisms, and the like), resulting in low accuracy and poor predictive power under abnormal conditions such as fast charging.

According to an embodiment, the full-order physics-based model refers to a structure that models physical phenomena inside an actual battery, such as lithium concentration distribution within the electrode, electrolyte conductivity, reaction current density, temperature changes, and metal plating/stripping phenomena, by using a complex partial differential equation (PDE) based on numerical analysis.

According to an embodiment, the full-order physics-based model may provide high accuracy, but it is not suitable for real-time computation due to its complex computational structure, which results in long computation times and high computational resource consumption.

According to an embodiment, the reduced-order physics-based model may numerically simplify the complex electrochemical and thermodynamic reactions occurring within an actual battery cell. In this way, the battery state may be predicted with sufficient accuracy while computational resources are saved.

According to an embodiment, the reduced-order physics-based model may include at least one of an electrochemical module, a thermal module, or a degradation module, or any combination thereof.

For example, the electrochemical module may model the diffusion, intercalation, and deintercalation of lithium ions within the electrode, and may predict a concentration distribution Cs of lithium ions, an electrode reaction rate ‘j’, a terminal voltage Vₜ, or the like.

For example, the thermal module may simulate the temporal change in battery temperature in consideration of electrochemical reaction heat and resistance heat generated during charging and discharging.

For example, the degradation module may reflect the decline in SOH by estimating degradation mechanisms such as capacity reduction according to an increase in a cycle count, an increase in internal resistance, Li-plating and stripping, SEI (solid electrolyte interphase) growth, or the like.

According to an embodiment, the processor 110 may determine a target charging current for shortening the charging time of the battery based on at least one of a negative pulse that induces stripping, in which metal plated from the battery is oxidized into metal ions, or the state of the battery, or any combination thereof.

According to an embodiment, the stripping may refer to a reaction in which the metal plated on the surface of the anode during battery charging is oxidized back into metal ions and returned to the electrolyte.

In general, lithium ions (Li+) on the surface of the battery's anode may be plated in the form of metallic lithium (Li) while being reduced with electrons during rapid charging, which may be a major cause of battery capacity loss or shortened lifespan.

The stripping may play a key role in preventing battery performance degradation and inducing stable charging by removing the plated metal.

According to an embodiment, the negative pulse may include applying a negative current in the reverse direction to the anode during a specific time interval during a general constant current charge (positive current).

The negative pulse may be used as a method of inducing the stripping reaction described above. In other words, the negative pulse may oxidize the metallic lithium plated on the anode surface via a temporary discharge operation so as to be returned to lithium ions.

According to an embodiment, the processor 110 may charge the battery with a target charging current that appropriately includes the negative pulse, thereby suppressing metal plating problems that may occur during the charging process and improving charging efficiency.

According to an embodiment, the target charging current may include a current determined to efficiently and safely charge the battery depending on the current battery state and charging conditions.

For example, the target charging current may be set to a value, which is dynamically adjusted based on a battery state and whether a negative pulse is applied, not a fixed value.

According to an embodiment, the processor 110 may dynamically determine the target charging current via an optimization algorithm considering battery state information and whether the negative pulse is applied.

For example, if it is determined that the certain amount of metallic lithium or more is plated, the processor 110 may induce the stripping via the negative pulse and then may adjust the charging pattern in a method of temporarily lowering or restoring the charging current thereafter.

Moreover, the processor 110 may restrict the target charging current such that the terminal voltage of the battery does not exceed a certain range, or may adjust the target charging current such that the difference in metal ion concentration does not exceed a threshold value.

In this way, the processor 110 may derive a charging strategy that satisfies both charging performance and safety, and in particular, may charge the battery in a shorter time compared to the conventional charging method using a multi-stage constant current (MCC).

In this way, the processor 110 may optimize the charging current based on the negative pulse and the battery state in consideration of the dynamic behavior (plating/stripping) of metallic lithium in the battery, thereby effectively suppressing factors that reduce the lifespan and safety while shortening the charging time of the battery.

According to an embodiment, the processor 110 may generate an algorithm for optimizing battery charging via a battery model, and may determine a target charging current by applying the algorithm to data associated with the state of the battery.

According to an embodiment, the processor 110 may generate an algorithm that optimizes battery charging based on the battery model.

According to an embodiment, an algorithm for optimizing the charging of a battery may include an algorithm capable of shortening the charging time while preventing performance degradation of the battery, by determining an appropriate charging current depending on the state of the battery.

For example, based on a battery model that reflects the battery's internal electrochemical reactions, the algorithm may predict various phenomena (Li-plating, an increase in heat generation, an increase in metal ion concentration deviation, an excessive increase in a voltage, and the like) that may occur during charging and may calculate the optimal charging current for controlling the predicted result in real time.

Furthermore, to shorten the charging time and to ensure the battery life at the same time, whether the negative pulse that induces the plated lithium to be oxidized into metal ions is applied, and the amplitude of the negative pulse may also be determined within the algorithm.

As a concrete example, the algorithm may be generated based on nonlinear model predictive control (NMPC).

According to an embodiment, the processor 110 may evaluate the charging condition of the battery in real time and may determine a target charging current suitable for the charging condition, by applying the generated algorithm to data associated with the state of the battery.

For example, if it is determined based on the data associated with the battery's state that phenomena occurring within the battery such as Li-plating or heat generation are likely to exceed a threshold level, the processor 110 may determine a current including a negative pulse or a low C-rate current as the target charging current.

For example, if it is determined that the battery condition is good and lithium stripping is capable of being effectively induced, the processor 110 may determine the target charging current for improving the charging rate, by applying a relatively high constant current.

In this way, the processor 110 may determine the optimal target charging current to efficiently shorten the charging time while ensuring the stability and lifespan of the battery, by applying an algorithm to the data associated with the battery state.

According to an embodiment, the processor 110 may determine the target charging current that minimizes or shortens the charging time of the battery the most while satisfying the charging condition for at least one of a heat generation rate of the battery, an extent to which Li-Plating (LiP) included in metal is suppressed, an extent to which Li-stripping (LiS) is induced, or minimization of capacity degradation of the battery (or an extent to which capacity degradation of the battery is reduced), or any combination thereof.

According to an embodiment, the processor 110 may determine the target charging current that satisfies the charging condition for the heat generation rate of the battery.

According to an embodiment, the processor 110 may pre-calculate the expected heat generation rate at a specific charging current by using a battery model, and may adjust the target charging current such that the heat generation rate does not exceed a predetermined threshold.

For example, the processor 110 may perform charge control in a method of reducing the charging rate in a section where the heat generation rate rapidly increases as the charging current increases, and permitting a relatively high current if heat generation is within a stable range.

According to an embodiment, the processor 110 may determine the target charging current that satisfies a charging condition for the extent to which LiP included in the metal is suppressed.

According to an embodiment, the processor 110 may predict the risk of Li-plating according to a charging current by using the battery model.

For example, the processor 110 may calculate indicators such as metal plating overpotential during charging, metal ion concentration gradient, plating current density during charging, or the like and may set conditions for adjusting the charging current such that these values do not exceed predetermined threshold values.

Furthermore, the processor 110 may recognize a situation, in which Li-plating is likely to occur, in advance by analyzing sensor data such as SOC, a temperature, a voltage, and a metal ion concentration in real time. If determining that Li-plating is likely to occur, the processor 110 may suppress Li-plating by lowering the charging current or including the negative pulse in the charging current.

According to an embodiment, the processor 110 may determine the target charging current that satisfies a charging condition for the extent to which Li-stripping (LiS) is induced.

According to an embodiment, if the negative pulse is applied, the processor 110 may analyze a condition under which Li-stripping (LiS) is effectively induced by using the battery model.

For example, the processor 110 may evaluate a stripping inducing condition by using indicators such as stripping current density at which Li-stripping effectively occurs, stripping overpotential, a recovery rate of metal ion concentration, or the like.

According to an embodiment, the processor 110 may determine the time point and the intensity of the negative pulse to be applied, in consideration of a charging history during a MCC section or at a past charging cycle, and the battery state. In this way, the processor 110 may set a charging condition that the plated lithium is effectively removed, by adjusting the time, at which stripping is induced, and the magnitude of the current including the negative pulse.

Moreover, the processor 110 may evaluate whether stripping is induced to a certain level or higher, based on changes in the battery's state (e.g., reduction in plating overpotential or recovery of metal ion concentration). If the stripping is determined to reach a certain level, the processor 110 may adjust the magnitude or duration of the negative pulse.

According to an embodiment, the processor 110 may determine the target charging current that satisfies a condition for minimizing capacity degradation of the battery.

For example, high charging current, excessive heat generation, Li-plating, or the like may cause changes in the electrode structure within the battery, abnormal growth of the SEI layer, and electrolyte decomposition, which may lead to a decrease in battery capacity.

The processor 110 may analyze, in real time, key indicators associated with battery capacity degradation such as an accumulated charge amount, a charging current profile, a battery temperature, metal plating overpotential, and a change rate of SOH, and may dynamically adjust the target charging current such that the indicators do not exceed predetermined reference values.

According to an embodiment, the processor 110 may determine the target charging current in comprehensive consideration of a charging condition of each of the heat generation rate of the battery, the extent to which Li-plating included in metal is suppressed, the extent to which Li-stripping is induced, or the minimization of battery capacity degradation (or the extent to which capacity degradation of the battery is reduced).

For example, the processor 110 may calculate the target charging current that satisfies a plurality of charging conditions such that Li-plating included in metal is while the heat generation rate simultaneously suppressed, occurring during charging does not exceed a predetermined threshold value, Li-stripping is effectively induced, and battery capacity degradation is minimized.

According to an embodiment, the processor 110 may determine the target charging current including a negative pulse based on NMPC.

The NMPC may be one of the predictive control techniques and may be designed to satisfy an objective function of a system by predicting a future operation of the system and calculating an optimal control input within a certain time interval.

The processor 110 may calculate the optimal value of the target charging current profile including whether to apply a negative pulse, a period of the negative pulse, the amplitude of the negative pulse, and duration of the negative pulse, based on a predefined objective function (e.g., a function of minimizing the battery charging time).

For example, the NMPC may simultaneously consider conditions such as whether the constant current charging time exceeds a predetermined reference time, whether the metal plating overpotential is maintained to be less than or equal to a threshold value, whether Li-stripping is effectively induced if a negative pulse is applied, and whether the terminal voltage of the battery does not rise excessively.

The processor 110 may set a nonlinear objective function for the above-described conditions and may determine the target charging current. For example, if including a negative pulse in the charging current is determined to improve charging efficiency and battery life, the processor 110 may derive an optimal target charging current including the negative pulse via the NMPC.

According to an embodiment, if a condition that the negative pulse is included in the target charging current is satisfied, the processor 110 may determine the target charging current including the negative pulse based on the NMPC.

According to an embodiment, the condition that the negative pulse is included in the target charging current may include at least one of a condition that a charging time during which a constant current is applied exceeds a predetermined first reference time, or a condition that a charging time during which a current including the negative pulse is applied is less than or equal to a predetermined second reference time, or any combination thereof.

According to an embodiment, if the condition that a charging time during which a constant current is applied exceeds the predetermined first reference satisfied, the processor 110 may determine the target charging current including the negative pulse based on the NMPC.

If the constant current (CC) is continuously applied to the battery, the risk of lithium ion concentration imbalance or metal plating inside the battery may increase. In particular, if fast charging continues for a long time in a low SOC range, a Li-plating phenomenon that lithium is plated on the surface of the anode and is fixed in a metallic form may occur. This may shorten a battery lifespan and may reduce safety.

Therefore, the processor 110 may continuously track the charging time during which the constant current is applied after charging starts, and may identify a case where the charging time during which constant current is applied exceeds a predetermined first reference time (e.g., 47 seconds).

If the charging time during which the constant current is applied is satisfied, the processor 110 may induce lithium stripping by including the negative pulse into the target charging current, and may adjust a charger algorithm to mitigate overpotential or a concentration gradient within the battery. According to an embodiment, if the condition that the charging time during which a current including the negative pulse is applied is less than or equal to a predetermined second reference time is satisfied, the processor 110 may determine the target charging current including the negative pulse based on the NMPC.

The lithium metal plated on the anode surface may be oxidized (stripped) back into ions by applying a reverse charging current for a short time using the negative pulse. However, if the time during which the current including the negative pulse is applied is excessively long, the charging efficiency may decrease and issues such as battery voltage instability may occur.

Accordingly, the processor 110 may continuously track the charging time during which the current including the negative pulse is applied, and may determine the target charging current such that the charging time does not exceed a predetermined second reference time (e.g., 3 seconds).

According to an embodiment, the processor 110 may determine the two conditions individually or in combination.

For example, if the charging time during which a current is applied exceeds the first reference time, and the charging time during which a current including a negative pulse is applied is less than or equal to the second reference time at the same time, the processor 110 may determine the target charging current including the negative pulse, based on the NMPC.

According to an embodiment, the processor 110 may determine the amplitude of the negative pulse based on at least one of a first condition that the terminal voltage of the battery does not exceed (e.g., is within) a range of a predetermined voltage, or a second condition that a difference between a metal ion concentration on the surface of the battery and the average metal ion concentration of the battery does not exceed (e.g., is less than or equal to) a predetermined threshold value, or any combination thereof.

According to an embodiment, the processor 110 may determine the amplitude of the negative pulse based on the first condition that the terminal voltage of the battery does not exceed the range of a predetermined voltage.

The processor 110 may prevent safety issues such as thermal runaway or electrical overload during charging by controlling the terminal voltage of the battery so as not to rise excessively. For example, if the terminal voltage rises abnormally while a current including the negative pulse is applied, this may include adverse effects on the entire battery system.

According to an embodiment, the processor 110 may determine the amplitude of the negative pulse that allows the terminal voltage of the battery not to exceed the range of the predetermined voltage.

For example, if MCC charging or a constant current charging continues during the charging process, the terminal voltage of the battery may gradually increase in proportion to the current. In this case, if it is detected that the terminal voltage approaches a threshold voltage, or the possibility that the terminal voltage exceeds the threshold voltage is detected, the processor 110 may reverse the current direction by immediately applying a negative pulse to the target charging current, and may temporarily lower the terminal voltage by switching to a discharging state.

The processor 110 may calculate a minimum pulse magnitude at which the terminal voltage remains within the range of a predetermined voltage.

According to an embodiment, the processor 110 may determine the magnitude of a negative pulse that allows a difference between a metal ion concentration on the surface of the battery and an average metal ion concentration of the battery not to exceed (e.g., less than or equal to) a predetermined threshold value.

To prevent the metal ion concentration gradient generated in the battery from becoming excessively great, the processor 110 may adjust the amplitude of the negative pulse.

The difference between the metal ion concentration on the surface of the battery and the average metal ion concentration of the battery may be further aggravated in a situation where the charging rate is fast or the current density is high. If the difference between the metal ion concentration on the battery surface and the average metal ion concentration of the battery increases, the accumulation of lithium ion on the battery surface increases, thereby increasing the possibility of Li-plating.

According to an embodiment, the processor 110 may determine the magnitude of a negative pulse that allows the maximum value of the difference between a metal ion concentration on the surface of the battery and an average metal ion concentration of the battery not to exceed (e.g., less than or equal to) a predetermined threshold value.

According to an embodiment, the processor 110 may determine the amplitude of the negative pulse based on the third condition that current density at which metal is plated from the battery does not exceed (e.g., is less than or equal to) current density at which metal ions are stripped from the battery.

For example, the current density at which metal is plated in the battery may mean the amount of metallic lithium plated on the surface of the anode during the charging process. If the current density at which metal is plated from the battery is excessive, the battery's lifespan may be reduced and the risk of a short circuit may increase.

For example, the current density at which metal ions are stripped may mean the amount of lithium metal plated on the anode surface that is ionized again and reduced to an electrolyte via a method such as a negative pulse.

According to an embodiment, the processor 110 may continuously determine a relative relationship between the current density at which metal is plated from the battery and the current density at which metal ions are stripped from the battery.

For example, if the plated current density exceeds the stripped current density, lithium may be accumulated in the battery, thereby reducing the charging efficiency of the battery.

Accordingly, the processor 110 may allow the plated current density so as not to exceed the stripped current density by adjusting the amplitude of the negative pulse.

According to an embodiment, based on the maximum value of the terminal voltage of the battery exceeding the predetermined voltage value, the target charging current may be determined as the current for maintaining a predetermined voltage value.

According to an embodiment, the processor 110 may monitor the maximum value of the terminal voltage of the battery in real time during the charging process. If the battery reaches an overpotential state, the risk of electrochemical imbalance, overheating, electrode damage, and shortened lifespan increases, and thus it is necessary to adjust the charging current so as not to exceed a specific threshold voltage.

According to an embodiment, if the terminal voltage of the battery exceeds the predetermined voltage value, the processor 110 may charge the battery with a current for allowing the terminal voltage to be maintained at the predetermined voltage value.

In other words, if the battery's terminal voltage exceeds the predetermined voltage value, the processor 110 may determine the target charging current as the current for allowing the terminal voltage to be maintained at the predetermined voltage value.

For example, if charging proceeds in a constant current method at the beginning of charging, and then the terminal voltage of the battery reaches the predetermined voltage value, the processor 110 may gradually reduce the charging current such that the terminal voltage of the battery maintains the predetermined voltage value. In this way, the processor 110 may prevent side effects that occur at a high voltage, such as Li-plating, and may increase the stability of the battery.

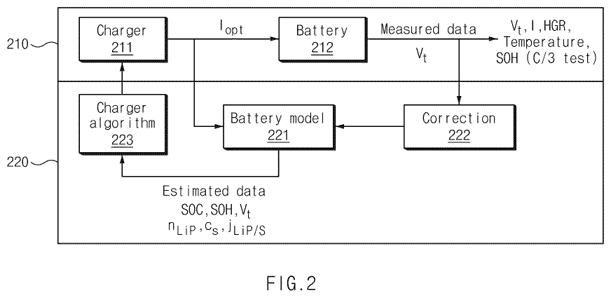

FIG. 2 is a block diagram illustrating a process in which a vehicle control apparatus according to an embodiment of the present disclosure applies a current determined based on a battery model and a charger algorithm to a battery.

According to an embodiment, FIG. 2 may be broadly divided into an upper region 210 and a lower region 220.

The upper region 210 includes a charger 211 and a battery 212 that are mounted on the vehicle, and may refer to a region where a charging operation is performed via hardware.

The lower region 220 includes a battery model 221, a correction module 222, and a charger algorithm 223, and may refer to a region where a charging operation is performed via software. For example, the vehicle control apparatus 100 may include the battery model 221, the correction module 222, and the charger algorithm 223.

According to an embodiment, the charger 211 may supply a current to the battery 212 based on an optimal charging current Iₒₚₜ received from a charger algorithm module.

According to an embodiment, measured data such as a terminal voltage Vₜ, a current ‘I’, a heat generation rate HGR, a temperature, SOH, or the like may be obtained from the battery 212. The measured data may be delivered to the correction module 222 and may be used for a correction task for improving the accuracy of model-based prediction.

According to an embodiment, the vehicle control apparatus 100 may receive data measured from a battery (such as battery 212) via the correction module 222 and may analyze an error. The vehicle control apparatus 100 may improve the accuracy of simulation by reflecting the analyzed error to the battery model 221.

According to an embodiments, the vehicle control apparatus 100 may numerically simulate the electrochemical characteristics and thermodynamic characteristics of the battery 212 based on data corrected via the battery model 221.

For example, the vehicle control apparatus 100 may predict state data of the battery 212 including SOC, SOH, a terminal voltage, Li-plating efficiency, surface concentration, or the like via the battery model 221.

According to an embodiment, the vehicle control apparatus 100 may apply the charger algorithm 223 based on the state data of the battery 212 received from the battery model 221. The vehicle control apparatus 100 may derive the optimal charging current suitable for charging the battery 212 via the charger algorithm 223.

For example, the vehicle control apparatus 100 may calculate the optimal charging current in comprehensive consideration of various conditions including Li-plating suppression, lithium stripping induction, heat generation rate limitation, capacity degradation suppression, or the like. The vehicle control apparatus 100 may deliver the calculated charging current information to the charger 211 and may control a charging process such that the corresponding charging current is actually applied to the battery 212.

Referring to FIG. 2 according to an embodiment, the vehicle control apparatus 100 may simultaneously achieve shortening of charging time, improvement of battery lifespan, and securing of safety by precisely predicting the battery state and controlling charging conditions in real time.

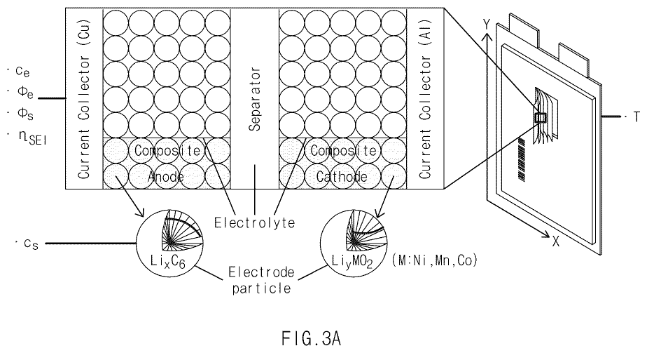

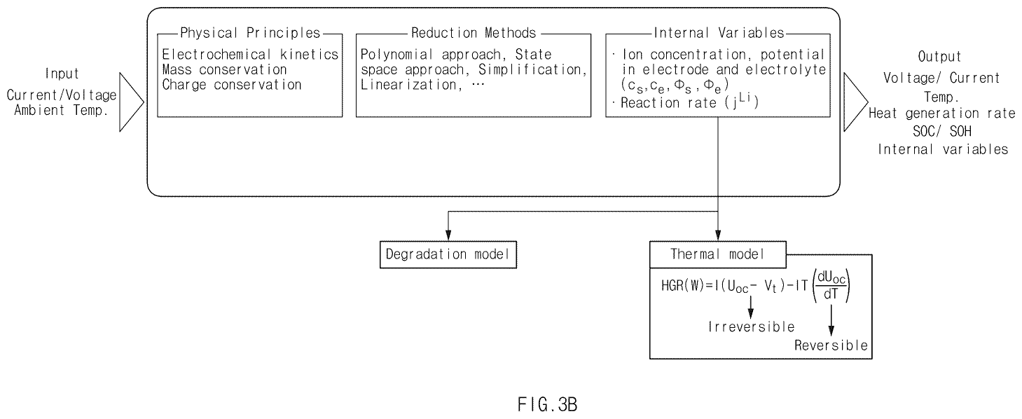

FIG. 3A is a schematic diagram illustrating a microcell, according to an embodiment of the present disclosure.

Referring to FIG. 3A, the microcell may be composed of a composite anode mixed with an electrolyte, a separator, and a composite cathode mixed with the electrolyte. The composite anode may be composed of lithium-intercalated graphite. If a cell is discharged, lithium ions may dissociate from the composite anode and may move via the electrolyte to the cathode. The composite cathode may be composed of lithium metal oxide. If the cell is charged, lithium ions may move via the electrolyte to the composite cathode and may be stored. The separator allows lithium ions to pass via the separator while physically separating the anode and the cathode. The electrolyte allows lithium ions to move between the anode and the cathode. The current collector provided at the anode and the cathode may operate as a passage for moving electrons generated during a process of charging or discharging the cell.

FIG. 3B is a diagram illustrating a structure of an electrochemical-thermal-life model, according to an embodiment of the present disclosure.

Referring to FIG. 3B, an electrochemical-thermal-life model refers to an electrochemical model based on a reduced-order model obtained by combining a thermal model and a degradation model.

If receiving internal variables, the thermal model may calculate and output a heat generation amount based on the internal variables. The heat generation amount may be expressed based on Equation 1.

$$HGR ( W ) = I ( {U}_{o c} - {V}_{t} ) - IT ( \frac{d {U}_{o c}}{d T} ) \qquad Equation 1$$

In Equation 1, ‘I’ denotes a current; Vₜ denotes a voltage at the time of ‘t’ seconds; ‘T’ is a temperature; U_{oc} denotes an open circuit voltage; and, dU_{oc}/dT is an entropic coefficient. The first term may represent an irreversible reaction, and the second term may represent a reversible reaction.

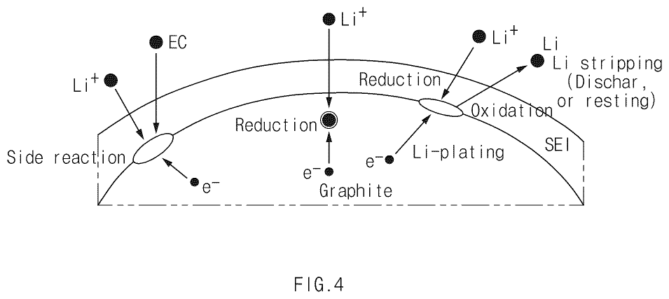

The degradation model may receive the internal variables and may calculate and output SOH and Li-plating overpotential by using the internal variables. Referring to FIG. 4, electrochemical degradation such as side reactions and Li-plating may occur during battery charging. The degradation model may predict the degradation and lifespan of a battery in consideration of the electrochemical degradation occurring during battery charging. In this case, the degradation model may consider electrochemical degradation that occurs under the following assumptions.

### Assumptions:

Deterioration occurs only at an anode.
Side reactions are irreversible reactions.
Li-plating is a semi-reversible reaction.
Mechanical degradation, gas generation, overcharge and overdischarge are not considered.

The degradation model may calculate a reaction rate and overpotential according to electrochemical degradation by using equations in Table 1.

TABLE 1

| | |
|---|---|
| | Main reaction |
| Reaction rate [A/cm³] | ${j}^{L i} = {a}_{s} {i}_{0} ( exp ( \frac{{α}_{ox} F}{RT} η ) - exp ( - \frac{{α}_{rd} F}{RT} η ) )$ |
| Overpotential | $η = {ϕ}_{s} - {ϕ}_{e} - {U}_{eq} - \frac{{R}_{SEI}}{{a}_{s}} {j}_{total}^{Li}$ |
| | Side reaction |
| Reaction rate [A/cm³] | ${j}_{side}^{Li} = - {a}_{s} {i}_{0 , side} exp ( - \frac{{α}_{rd , side} {n}_{side} F}{RT} {η}_{side} )$ |
| Overpotential | ${η}_{side} = {ϕ}_{s} - {ϕ}_{e} - {U}_{eq , side} - \frac{{R}_{SEI}}{{a}_{s}} {j}_{total}^{Li}$ |
| | Lithium plating/stripping |
| Reaction rate [A/cm³] | ${j}_{LiP}^{Li} = - {a}_{s} {i}_{0 , Li} exp ( - \frac{{α}_{rd , Li} F}{RT} {η}_{LiP} )$ |
| Overpotential | $\begin{matrix}{η}_{LiP} = {ϕ}_{s} - {ϕ}_{e} - {U}_{eq , LiP} - \frac{{R}_{SEI}}{{a}_{s}} {j}_{total}^{Li} \\ {η}_{LiP} = min ( {η}_{LiP} , 0 )\end{matrix}$ |
| Total reaction rate | ${j}_{total}^{Li} = {j}^{Li} + {j}_{side}^{Li} + {j}_{LiP}^{Li}$ |

In Table 1, as denotes a specific reaction area, and R_{SEI} denotes the resistance of SEI. αₒₓ, α_{rd}, α_{rd,side}, and α_{rd,Li}, denote constants; ‘F’ denotes a Faraday constant; ‘R’ denotes resistance; and, ‘T’ denotes a temperature. U_{eq} denotes equilibrium potential of a main reaction; and, V_{eq,side} denotes equilibrium potential of a side reaction. n_{side} denotes the number of ions that participate in the side reaction. i₀ denotes exchange current density, which may be expressed as in Equation 2.

$${i}_{0} = {k ( {c}_{e} )}^{{a}_{o x}} {( {c}_{s , max} - {c}_{s} )}^{{α}_{o x}} {c}_{s}^{{α}_{r d}} \qquad Equation 2$$

In Equation 2, ‘k’ denotes a kinetic rate constant.

FIG. 4 is a diagram showing an electrochemical mechanism, in which lithium ions are stripped by a vehicle control apparatus, according to an embodiment of the present disclosure.

According to an embodiment, FIG. 4 visually represents various reaction processes occurring on an anode interphase of a lithium ion battery, and particularly includes a process of Li-plating during charging and Li-stripping during discharging.

According to an embodiment, the SEI of FIG. 4 may be a stable solid layer formed between an electrolyte and an anode (e.g., graphite), and may be formed after the electrolyte is reduced during an initial charging process.

The SEI may include properties that allow lithium ions to pass via the SEI but to block electrons.

In the upper portion of FIG. 4, lithium ions (Li+) moving within the electrolyte are shown. The lithium ions (Li+) may be plated as metallic lithium (Li) via a reduction reaction on an electrode surface. A process in which lithium ions receive electrons and are converted into metallic lithium is expressed as “Li plating,” which is an undesirable phenomenon that may occur during charging at an excessive current or a low temperature.

In an embodiment, a vehicle control apparatus may induce a Li-stripping reaction of oxidizing the plated lithium again so as to be converted it into lithium ions, by applying a charging current including a negative pulse.

In FIG. 4, the Li-stripping process is shown as a path indicated as “Oxidation,” which may mean a process in which the plated metallic lithium releases electrons again and is oxidized into lithium ions so as to return to an electrolyte.

The vehicle control apparatus according to an embodiment may induce a Li-stripping reaction that oxidizes lithium metal plated on the surface of an anode according to the mechanism illustrated in FIG. 4 so as to return to lithium ions, by applying the charging current including a negative pulse to the battery.

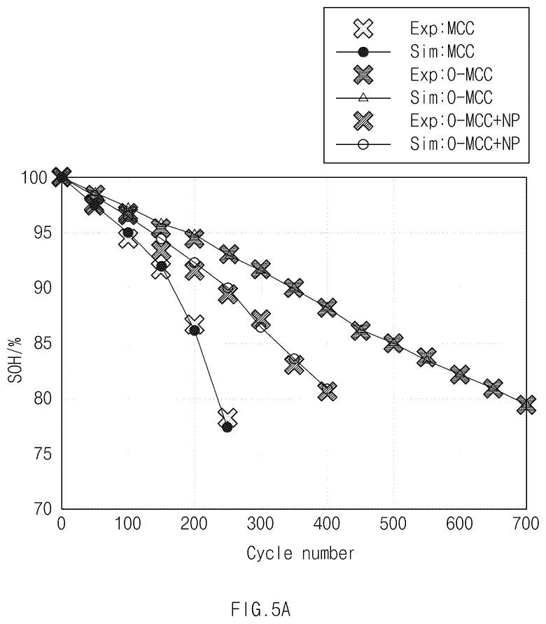

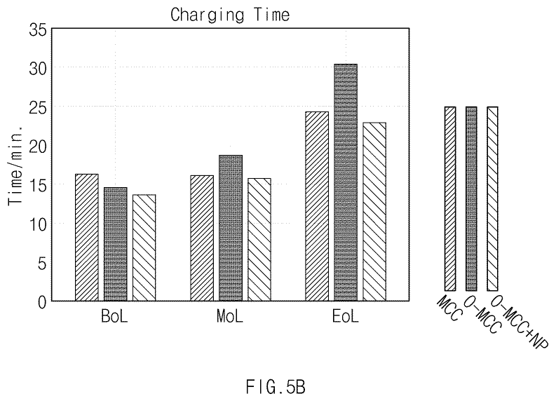

FIG. 5A is a graph illustrating a simulation result showing that SOH of a battery is improved as a vehicle control apparatus according to an embodiment of the present disclosure includes a negative pulse in a target charging current.

FIG. 5A is a graph for comparing a change in SOH according to the number of charge/discharge cycles if a battery is charged/discharged depending on three charging protocols: MCC, O-MCC, and O-MCC+NP.

A MCC method refers to a method of charging the battery in each step of a constant current, and may control a charging rate while a charging current is fixed for each step. In general, this may include a method of initially charging the battery at a high current and gradually lowering the charging current as the SOC increases. The MCC method includes a simple structure and is easy to implement. However, it may not sufficiently suppress side effects such as Li-plating or heat generation, thereby causing rapid battery degradation.

Referring to FIG. 5A according to an embodiment, the MCC method (Exp: MCC, Sim: MCC) shows that SOH decreases relatively quickly and there is rapid degradation after about 250 cycles.

The O-MCC may be based on the MCC method, but may include a method that optimizes the current magnitude and duration of each charging stage in consideration of the battery's state (SOC, SOH, voltage, and the like). A vehicle control apparatus may adjust a charging profile to minimize degradation and increase efficiency by using a battery model and state data. In this way, charging efficiency and lifespan characteristics may be improved compared to the MCC.

Referring to FIG. 5A according to an embodiment, the O-MCC method (Exp: O-MCC, Sim: O-MCC) alleviates a battery deterioration rate by optimizing the charging current, and the SOH degradation curve appears gentle.

The O-MCC+NP may refer to a method of adding a negative pulse to the O-MCC method, and may apply a negative current (a discharge current) at a regular time interval during optimized constant current charging. Li-stripping is induced to convert lithium metal plated on the anode back into lithium ions by using the negative pulse, and degradation due to metal plating is alleviated. As a result, SOH may be maintained most stably in long-term cycles.

Referring to FIG. 5A according to an embodiment, it is identified that the O-MCC+NP method (Exp: O-MCC+NP, Sim: O-MCC+NP) suppresses Li-plating and induces Li-stripping by adding a negative pulse to the O-MCC method, thereby improving the state retention rate of the battery during long-term cycling. The simulation results also show a similar trend to the experimental results, and the validity of the proposed vehicle control apparatus and the proposed charger algorithm is demonstrated.

These results indicate that a charging profile including a negative pulse effectively controls a degradation mechanism of the battery and, as a result, contributes to a longer battery life.

FIG. 5B is a graph showing a simulation result showing that a charging time is shortened as a vehicle control apparatus according to an embodiment of the present disclosure includes a negative pulse in a target charging current.

According to an embodiment, FIG. 5B illustrates simulation results demonstrating that a vehicle control apparatus according to an embodiment of the present disclosure may effectively shorten a charging time according to the battery's life cycle stage (Beginning of Life (BOL)/Middle of Life (MOL)/End of Life (EoL)) by applying a charging protocol including a negative pulse.

Referring to FIG. 5B, in the BOL section, the charging time of a MCC method appears to be the longest. The reason is that in the initial stage, MCC uniformly applies the set charging stage, resulting in non-optimized free current. On the other hand, O-MCC and O-MCC+NP achieve a relatively short charging time by using optimized current profiles considering the initial battery state.

Referring to FIG. 5B, in the MoL section, charging times of the three methods are similar to each other, but the O-MCC+NP still maintains the shortest charging time. This shows that the O-MCC+NP method demonstrates the most efficient charging performance as Li-stripping is effectively induced via a negative pulse even in the mid-term in which battery performance gradually deteriorates.

Referring to FIG. 5B, the charging time tends to increase overall in the EoL section. In the case, the charging time of the O-MCC may be longer than that of the MCC or the O-MCC+NP, which may be interpreted as the O-MCC applies a conservative charging current by reflecting battery aging.

On the other hand, the O-MCC+NP method still maintains the shortest charging time among the three methods. The reason is that charging efficiency is consistently maintained by effectively suppressing Li-plating via the negative pulse and inducing metallic lithium stripping.

As a result, FIG. 5B visually shows that the O-MCC+NP charging method applied by the vehicle control apparatus according to an embodiment of the present disclosure may shorten the charging time over the battery life cycle. In particular, the O-MCC+NP charging method records the shortest charging time in the EoL section, and it suggests the possibility of simultaneously satisfying two conflicting goals: fast charging and battery life preservation.

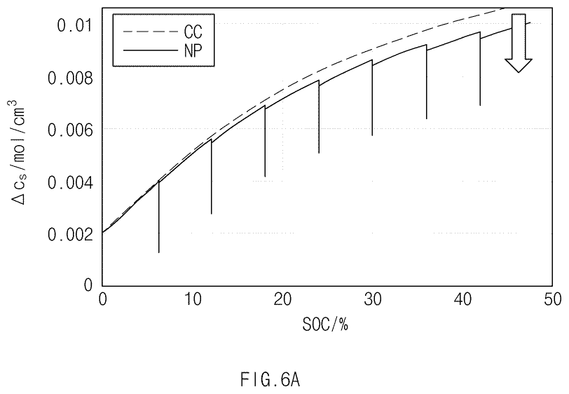

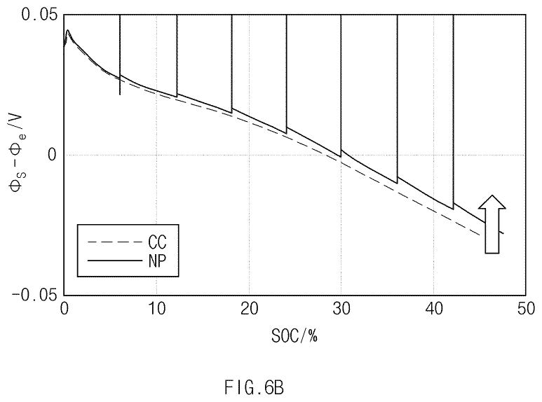

FIG. 6A is a graph obtained by comparing trends of lithium concentration gradient changes in charging by a constant current and charging by a current including a negative pulse depending on SOC, according to an embodiment of the present disclosure.

A lithium ion concentration n gradient may mean a difference between the metal ion concentration on the surface of a battery and the average metal ion concentration of the battery. In the graph shown in FIG. 6A, a solid line may indicate a charging method including a negative pulse (NP), and a dotted line may indicate a constant current (CC) charging method.

As shown in FIG. 6A, the CC charging method shows a trend in which the lithium ion concentration gradient gradually increases as the SOC increases.

On the on the other hand, a section where the lithium concentration gradient decreases at regular SOC intervals is observed in the charging method including the NP. This may be seen as a stripping reaction that alleviates the difference between the lithium concentration on the anode surface and the average concentration if the NP is applied.

Accordingly, the charging method including the NP suppresses the cumulative increase in the lithium concentration gradient even though SOC increases, and as a result, the difference in the lithium concentration gradient may be kept to be lower than that of CC charging.

FIG. 6A according to an embodiment may suggest that a vehicle control apparatus may effectively improve the uniformity of lithium ion concentration distribution via a target charging current including the NP.

FIG. 6B is a graph obtained by comparing changes in metal plating overpotential in charging by a constant current and charging by a current including a negative pulse depending on SOC, according to an embodiment of the present disclosure.

The graph shown in FIG. 6B shows the result of comparing the change trend of metal plating overpotential φₛ-φₑ based on a charging method, depending on SOC. Here, a solid line may indicate a charging method including NP, and a dotted line may indicate a CC charging method.

In the graph shown in FIG. 6B, it may be implied that metallic Li-plating may be promoted on a surface at the SOC where the metal plating overpotential is less than 0 V.

Referring to FIG. 6B, it may be seen that the metal plating overpotential increases in a charging method by a current including a negative pulse. This reflects a phenomenon that the metallic Li-plating on an anode surface is oxidized back to an ionic state, and then the overpotential is alleviated while the Li-stripping reaction is induced by the negative pulse.

As a result, compared to a charging method by the constant current, the average overpotential level in the entire charging section by the current charging method including the negative pulse may be maintained to be high.

Accordingly, the SOC at which the metal plating overpotential becomes less than 0 V may be delayed.

As such, the result may indicate that the negative pulse contributes to delaying a time point of reaching a plating threshold condition by periodically alleviating the excessive overpotential state, which is one of the main causes of Li-plating.

Accordingly, FIG. 6B includes simulation results supporting that the charging control method according to an embodiment of the present disclosure including a negative pulse may reduce the risk of metal plating and may contribute to maintaining long-term battery performance.

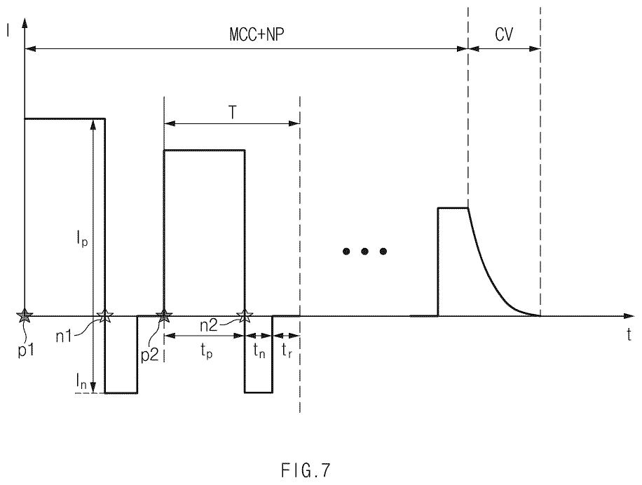

FIG. 7 is a diagram illustrating a process in which a vehicle control apparatus according to an embodiment of the present disclosure optimally determines a constant current magnitude and amplitude of a negative pulse using NMPC.

FIG. 7 is a diagram visualizing a process in which a vehicle control apparatus according to an embodiment of the present disclosure predicts and controls the magnitude of MCC and the amplitude of NP using NMPC as a current waveform over time.

As shown in FIG. 7, a negative pulse is periodically inserted during the MCC+NP charging step, which induces Li-stripping and ionizes the plated lithium, thereby contributing to improving the lifespan of a battery.

In FIG. 7, ‘p1’ and ‘p2’ may refer to time points at which a MCC magnitude Iₚ is determined by using NMPC, and ‘n1’ and ‘n2’ may refer to time points at which an NP amplitude Iₙ is determined by using NMPC.

According to an embodiment, the vehicle control apparatus may determine the MCC magnitude Iₚ by using NMPC based on Equation 3.

$$J = {min}_{{I}_{p} ( t )} ( {\sum }_{t}^{t + {N}_{p}} {I}_{p} ) \qquad Equation 3$$

Equation 3 may mean that the vehicle control apparatus establishes a charging strategy to minimize the sum of the charging current Iₚ during a predicted section Nₚ. In other words, Equation 3 may be intended to find an optimal Iₚ(t) such that the total amount of a current profile is minimized.

According to an embodiments, the vehicle control apparatus may apply a current magnitude limit condition −a≤Iₚ≤−b to determine the magnitude of the charging current Iₚ.

The current magnitude limit condition may refer to a condition for setting the range of current applicable in a MCC charging section. In one embodiment, the parameter ‘a’ may define a minimum allowable magnitude of the charging current Iₚ within a multi-stage constant current (MCC) section, whereas the parameter ‘b’ may define a maximum allowable magnitude of Iₚ. The values of ‘a’ and ‘b’ may be determined based on safety margins or degradation thresholds of the battery.

‘C’ may be the rated capacity standard (C-rate), and this constraint condition may be intended to prevent battery degradation by only allowing a gentle charging current of a specific level or less, not a relatively great current.

According to an embodiment, to determine the magnitude of the charging current Iₚ, the vehicle control apparatus may apply at least one of a lithium concentration gradient limit condition max(c_{s,surf}−c_{s,ave})≤c. The parameter c may be defined to prevent excessive lithium plating or degradation of electrode materials by ensuring that the internal lithium diffusion does not exceed a critical gradient level during charging.

c_{s,surf} may refer to the lithium concentration on the surface of the battery, and c_{s,ave} may refer to the average lithium concentration of the battery.

According to an embodiments, the vehicle control apparatus may determine the NP amplitude Iₙ by using NMPC based on Equation 4.

$$J = {min}_{{I}_{n} ( t )} ( {\sum }_{t}^{t + {N}_{n}} {I}_{n} ) \qquad Equation 4$$

Equation 4 may mean that the vehicle control apparatus establishes a charging strategy to minimize the sum of the negative pulse current Iₙ during a predicted section Nₙ. In other words, an optimal Iₙ(t) for minimizing the total amount of the current profile may be obtained such that the negative pulse for stripping is not unnecessarily applied to a current.

According to an embodiment, the vehicle control apparatus may apply a current magnitude limit condition d≤Iₙ≤e to determine the amplitude of the negative pulse current Iₙ.

The current magnitude limit condition may refer to a condition for setting the range of current applicable in a negative pulse section.

‘C’ may be the rated capacity standard (C-rate), and this constraint condition may be intended to limit the current magnitude within an appropriate range, considering that the negative pulse needs to operate with a strong current of a specific level or higher to effectively induce Li-stripping. Moreover, the vehicle control apparatus may apply a voltage limit condition f≤Vₜ≤g to determine the amplitude of the negative pulse current Iₙ.

The voltage limit condition may be intended to maintain the stability and lifespan of the battery by preventing a cell voltage from becoming excessively low or high while a negative pulse is applied.

Furthermore, the vehicle control apparatus may apply a lithium concentration gradient limit condition max(c_{s,surf}−c_{s,ave})≤c to determine the amplitude of the negative pulse current Iₙ.

c_{s,surf} may refer to the lithium concentration on the surface of the battery, and c_{s,ave} may refer to the average lithium concentration of the battery.

These constraint conditions may be intended to prevent abnormal electrochemical reactions such as the plating of metallic lithium by suppressing the formation of an excessive lithium concentration gradient within the battery.

According to an embodiment, the vehicle control apparatus may flexibly determine the magnitude of the current by selectively applying one or more of the above-described constraint conditions or by applying a combination of these conditions in a complex way.

In FIG. 7, a constant voltage (CV) section is indicated as the last step, which may mean a section that gradually reduces the charging current while a constant voltage is maintained if the battery terminal voltage exceeds a set threshold value (e.g., 4.15 V). In this section, under the control of the vehicle control apparatus, battery damage may be prevented by adjusting the current based on the battery voltage.

In summary, FIG. 7 is a diagram showing that an NMPC-based charge control method may optimize the magnitude of a constant current and the amplitude of a negative pulse in real time in each charge section, thereby simultaneously improving battery performance and lifespan.

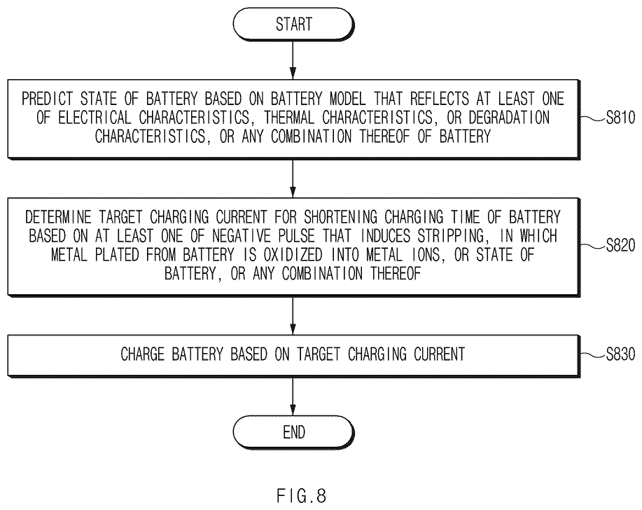

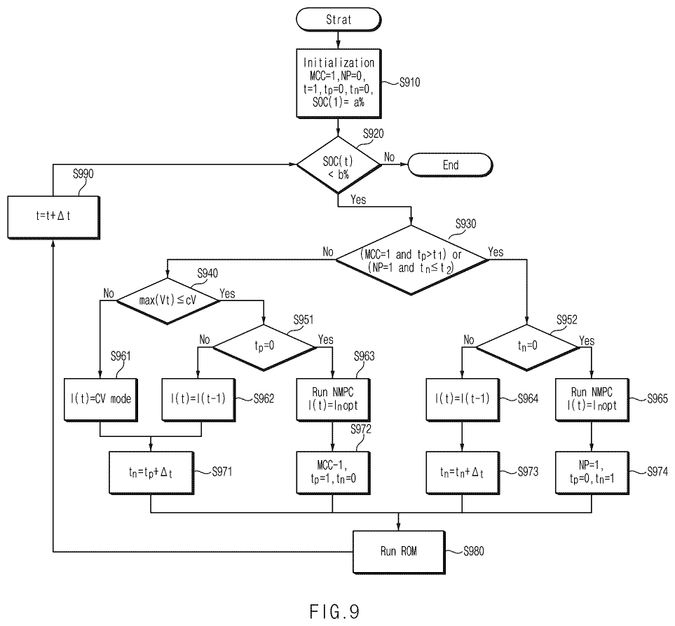

Hereinbelow, a vehicle control apparatus or a vehicle control method according to an embodiment of the present disclosure is described with reference to FIGS. 8 and 9.

Hereinbelow, the vehicle control apparatus 100 of FIG. 1 may perform the process of FIG. 8 or FIG. 9.

FIG. 8 is a flowchart for describing a vehicle control apparatus or a vehicle control method, according to an embodiment of the present disclosure.

According to an embodiment, a processor of the vehicle control apparatus (such as the processor 110 of the vehicle control apparatus 100 of FIG. 1) may perform an operation of predicting the state of the battery based on a battery model that reflects at least one of electrical characteristics, thermal characteristics, or degradation characteristics, or any combination thereof of a battery (S810).

According to an embodiment, the processor of the vehicle control apparatus may perform an operation of determining a target charging current for shortening the charging time of the battery based on at least one of a negative pulse that induces stripping, in which metal plated from the battery is oxidized into metal ions, or the state of the battery, or any combination thereof (S820).

According to an embodiment, the processor of the vehicle control apparatus may perform an operation of charging the battery based on the target charging current (S830).

FIG. 9 is a flowchart illustrating a process for determining whether a vehicle control apparatus according to an embodiment of the present disclosure determines a target charging current including a negative pulse.

According to an embodiment, a vehicle control apparatus may initialize algorithm data to MCC=1, NP=0, t=1, tₚ=0, tₙ=0, and SOC (1)=a % (S910).

According to an embodiment, the vehicle control apparatus may determine whether SOC at a current time ‘t’ is less than a threshold value b % (S920). This may mean a step of determining whether a battery needs to be charged.

According to an embodiment, the vehicle control apparatus may check a condition for determining whether to perform a charging mode applying a negative pulse, or whether to perform a charging mode applying only a constant current (S930).

For example, the vehicle control apparatus may determine whether at least one of a condition (MCC=1 and tₚ>t₁) that a charging time during which a constant current is applied exceeds a predetermined first reference time, or a condition (NP=1 and tₙ≤t₂) that a charging time during which a current including the negative pulse is applied is less than or equal to a predetermined second reference time, or any combination thereof is satisfied.

If the condition of S930 is not satisfied (No in S930), the vehicle control apparatus may determine whether the maximum value (e.g., the highest value) of the battery's terminal voltage is less than or equal to a predetermined voltage value max (Vₜ)≤c (S940).

If the maximum value of the terminal voltage of the battery exceeds a predetermined voltage value (No in S940), the vehicle control apparatus may proceed to a constant voltage mode (CV).

If the maximum value of the terminal voltage of the battery is less than or equal to the predetermined voltage value (Yes in S940), the vehicle control apparatus may determine whether tₚ=0 (S951).

If tₚ=0 is not established (No in S951), the vehicle control apparatus may maintain the magnitude of the previously applied current (S962).

If proceeding in the constant voltage mode (CV) or maintaining the magnitude of the previously applied current, the vehicle control apparatus may set algorithm data to “tₙ=tₚ+Δt” (S971).

If tₚ=0 is established (Yes in S951), the vehicle control apparatus may derive the optimal MCC current In by executing NMPC (S963). Afterwards, the vehicle control apparatus may set the algorithm data to MCC=1, tₚ=1, and tₙ=0 (S972).

If the condition of S930 is satisfied (Yes in S930), the vehicle control apparatus may determine whether tₙ=0 (S952).

If tₙ=0 is not established (No in S952), the vehicle control apparatus may maintain the magnitude of the previously applied current (S964).

If the magnitude of the previously applied current is maintained, the vehicle control apparatus may set the algorithm data to tₙ=tₚ+Δt (S973).

If tₙ=0 is established (Yes in S952), the vehicle control apparatus may derive the optimal negative pulse current Iₙ by executing NMPC (S965). Afterwards, the vehicle control apparatus may set the algorithm data to NP=1, tₚ=0, tₙ=1 (S974).

Afterwards, the vehicle control apparatus may update a system state or may update the prediction result by executing a Reduced Order Model (ROM) (S980).

If updating the prediction result via the ROM, the vehicle control apparatus may increase the time ‘t’ by Δt (S990) and repeat the loop (S990).

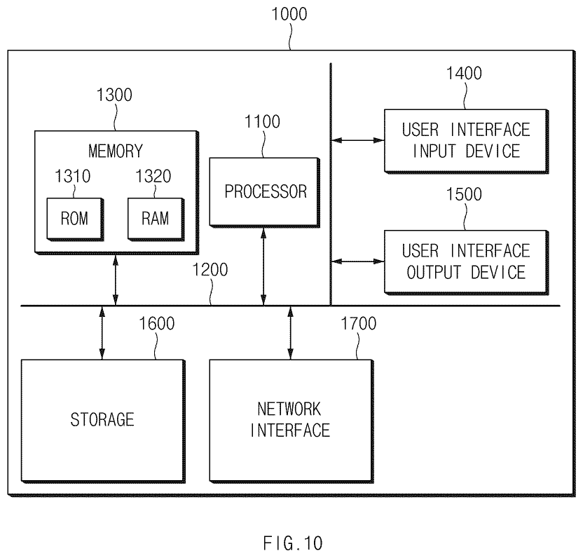

FIG. 10 shows a diagram illustrating a computing system associated with a vehicle control apparatus or a vehicle control method, according to an embodiment of the present disclosure.

Referring to FIG. 10, a computing system 1000 may include at least one processor 1100, a memory 1300, a user interface input device 1400, a user interface output device 1500, storage 1600, and a network interface 1700, which are connected with each other via a bus 1200.

The processor 1100 may be a central processing unit (CPU) or a semiconductor device that processes instructions stored in the memory 1300 and/or the storage 1600. Each of the memory 1300 and the storage 1600 may include various types of volatile or nonvolatile storage media. For example, the memory 1300 may include a read only memory (ROM) 1310 and a random access memory (RAM) 1320.

Accordingly, the operations of the method or algorithm described in connection with s disclosed in the specification may be directly implemented with a hardware module, a software module, or the combination of the hardware module and the software module, which is executed by the processor 1100. The software module may reside on a storage medium (i.e., the memory 1300 and/or the storage 1600) such as a random access memory (RAM), a flash memory, a read only memory (ROM), an erasable and programmable ROM (EPROM), an electrically EPROM (EEPROM), a register, a hard disk drive, a removable disc, or a compact disc-ROM (CD-ROM).

The storage medium may be coupled to the processor 1100. The processor 1100 may read out information from the storage medium and may write information in the storage medium. Alternatively, the storage medium may be integrated with the processor 1100. The processor and storage medium may be implemented with an application specific integrated circuit (ASIC). The ASIC may be provided in a user terminal. Alternatively, the processor and storage medium may be implemented with separate components in the user terminal.

The above description is merely an example of the technical idea of the present disclosure, and various modifications and variations may be made by one having ordinary skill in the art without departing from the essential characteristic of the present disclosure.

Accordingly, embodiments of the present disclosure are intended not to limit but to explain the technical idea of the present disclosure, and the scope and spirit of the present disclosure is not limited by the above embodiments. The scope of protection of the present disclosure should be construed by the attached claims, and all equivalents thereof should be construed as being included within the scope of the present disclosure.

One or more embodiments of the present disclosure may induce lithium stripping by including a negative pulse in a current for charging a battery.

One or more embodiments of the present disclosure may improve the lifespan and safety of the battery by removing lithium plated from a battery surface via lithium stripping.

Moreover, one or more embodiments of the present disclosure may determine whether to apply a negative pulse and may determine an optimal charging current for a battery by reflecting the lithium stripping effect according thereto.

Furthermore, one or more embodiments of the present disclosure may derive the optimal charging current that satisfies both charging performance and safety by considering the metal stripping reaction induced by the negative pulse.

Furthermore, one or more embodiments of the present disclosure may dynamically determine the optimal current for the battery, which is being charged, based on the battery's state data.

Also, one or more embodiments of the present disclosure may determine the amplitude of the negative pulse so as not to increase the overall charging time while minimizing the growth of lithium plated from the surface of the battery.

In addition, a variety of effects directly or indirectly understood via the present disclosure may be provided.

Hereinabove, although the present disclosure was described with reference to embodiments and the accompanying drawings, the present disclosure is not limited thereto, but may be variously modified and altered by those having ordinary skill in the art to which the present disclosure pertains without departing from the spirit and scope of the present disclosure claimed in the following claims.

What is claimed is:

1. A vehicle control apparatus comprising:
a memory configured to store program instructions; and
a processor configured to execute the program instructions,
wherein the processor is configured to:
determine a state of a battery based on a battery model that considers at least one of an electrical characteristic, a thermal characteristic, a degradation characteristic, or any combination thereof of the battery;
determine a target charging current for shortening a charging time of the battery based on at least one of a negative pulse that induces stripping where metal plated from the battery is oxidized into metal ions, or the state of the battery, or any combination thereof; and
charge the battery based on the target charging current.

2. The vehicle control apparatus of claim 1, wherein the processor is further configured to:
generate an algorithm for optimizing charging of the battery via the battery model; and
determine the target charging current by applying the algorithm to data associated with the state of the battery.

3. The vehicle control apparatus of claim 1, wherein the processor is further configured to:
determine the target charging current that shortens the charging time of the battery the most while satisfying a charging condition for at least one of a heat generation rate of the battery, an extent to which plating of lithium included in the metal is suppressed, an extent to which stripping of the lithium is induced, or an extent to which capacity degradation of the battery is reduced, or any combination thereof.

4. The vehicle control apparatus of claim 1, wherein the processor is further configured to:
determine the target charging current including the negative pulse based on nonlinear model predictive control.

5. The vehicle control apparatus of claim 1, wherein the processor is further configured to:
determine the target charging current including the negative pulse based on nonlinear model predictive control based on a condition that the negative pulse is included in the target charging current being satisfied, and
wherein the condition that the negative pulse is included in the target charging current includes
at least one of a condition that a charging time during which a constant current is applied exceeds a predetermined first reference time, or a condition that a charging time during which a current including the negative pulse is applied is less than or equal to a predetermined second reference time, or any combination thereof.

6. The vehicle control apparatus of claim 1, wherein the processor is further configured to:
determine amplitude of the negative pulse based on at least one of a first condition that a terminal voltage of the battery is within a range of a predetermined voltage, or a second condition that a difference between a metal ion concentration on a surface of the battery and an average metal ion concentration of the battery is less than or equal to a predetermined threshold value, or any combination thereof.

7. The vehicle control apparatus of claim 1, wherein the processor is configured to:
determine amplitude of the negative pulse based on a third condition that current density at which the metal is plated from the battery is less than or equal to current density at which metal ions are stripped from the battery.

8. The vehicle control apparatus of claim 1, wherein the processor is further configured to:
determine the target charging current as a current for maintaining a predetermined voltage value based on a highest value of a terminal voltage of the battery exceeding the predetermined voltage value.

9. The vehicle control apparatus of claim 1, wherein the processor is further configured to:
determine data associated with the state of the battery by using a sensor installed in the battery, and
wherein the data associated with the state of the battery includes
at least one of State of Charge (SOC), State of Health (SOH), a terminal voltage of the battery, an overpotential at which the metal is plated from the battery, a metal ion concentration on a surface of the battery, an average metal ion concentration of the battery, current density at which the metal is plated from the battery, or current density at which metal ions are stripped from the battery, or any combination thereof.

10. The vehicle control apparatus of claim 1, wherein the processor is further configured to:
determine the state of the battery based on a reduced-order physics-based model.

11. A vehicle control method, the method comprising:
determining, by a processor, a state of a battery based on a battery model that considers at least one of an electrical characteristic, a thermal characteristic, a degradation characteristic, or any combination thereof of the battery;
determining, by the processor, a target charging current for shortening a charging time of the battery based on at least one of a negative pulse that induces stripping where metal plated from the battery is oxidized into metal ions, or the state of the battery, or any combination thereof; and
charging, by the processor, the battery based on the target charging current.

12. The method of claim 11, wherein determining, by the processor, the target shortening the charging time of the battery includes:
generating, by the processor, an algorithm for optimizing charging of the battery via the battery model; and
determining, by the processor, the target charging current by applying the algorithm to data associated with the state of the battery.

13. The method of claim 11, wherein determining, by the processor, the target charging current for shortening the charging time of the battery includes:
determining, by the processor, the target charging current that shortens the charging time of the battery the most while satisfying a charging condition for at least one of a heat generation rate of the battery, an extent to which plating of lithium included in the metal is suppressed, an extent to which stripping of the lithium is induced, or an extent to which capacity degradation of the battery is reduced, or any combination thereof.

14. The method of claim 11, wherein determining, by the processor, the target charging current for shortening the charging time of the battery includes:
determining, by the processor, the target charging current including the negative pulse based on nonlinear model predictive control.

15. The method of claim 11, wherein determining, by the processor, the target charging current for shortening the charging time of the battery includes:
determining, by the processor, the target charging current including the negative pulse based on nonlinear model predictive control based on a condition that the negative pulse is included in the target charging current being satisfied, and
wherein the condition that the negative pulse is included in the target charging current includes
at least one of a condition that a charging time during which a constant current is applied exceeds a predetermined first reference time, or a condition that a charging time during which a current including the negative pulse is applied is less than or equal to a predetermined second reference time, or any combination thereof.

16. The method of claim 11, wherein determining, by the processor, the target charging current for shortening the charging time of the battery includes:
determining, by the processor, amplitude of the negative pulse based on at least one of a first condition that a terminal voltage of the battery is within a range of a predetermined voltage, or a second condition that a difference between a metal ion concentration on a surface of the battery and an average metal ion concentration of the battery is less than or equal to a predetermined threshold value, or any combination thereof.

17. The method of claim 11, wherein determining, by the processor, the target charging current for shortening the charging time of the battery includes:
determining, by the processor, amplitude of the negative pulse based on a third condition that current density at which the metal is plated from the battery is less than or equal to current density at which metal ions are stripped from the battery.

18. The method of claim 11, wherein determining, by the processor, the target charging current for shortening the charging time of the battery includes:
determining, by the processor, the target charging current as a current for maintaining a predetermined voltage value based on a highest value of a terminal voltage of the battery exceeding the predetermined voltage value.

19. The method of claim 11, further comprising:
determining, by the processor, data associated with the state of the battery by using a sensor installed in the battery,
wherein the data associated with the state of the battery includes
at least one of SOC, SOH, a terminal voltage of the battery, an overpotential at which the metal is plated from the battery, a metal ion concentration on a surface of the battery, an average metal ion concentration of the battery, current density at which the metal is plated from the battery, or current density at which metal ions are stripped from the battery, or any combination thereof.

20. The method of claim 11, wherein determining, by the processor, the state of the battery includes:
determining, by the processor, the state of the battery based on a reduced-order physics-based model.
